(19) United States
(12) Patent Application Publication
(10) Pub. No.: US 2022/0298417 A1
(43) Pub. Date: Sep. 22, 2022

(54) Liquid Compositions For Selectively Removing Polysilicon Over P-Doped Silicon And Silicon-Germanium During Manufacture Of A Semiconductor Device

(71) Applicant: Versum Materials US, LLC, Tempe, AZ (US)

(72) Inventors: Wen Dar Liu, Chupei City (TW); YI-CHIA LEE, Chupei City (TW); CHUNG-YI CHANG, New Taipei City (TW); AIPING WU, Chandler, AZ (US); LAISHENG SUN, Gilbert, AZ (US)

(73) Assignee: Versum Materials US, LLC, Tempe, AZ (US)

(21) Appl. No.: 17/596,078

(22) PCT Filed: Jun. 12, 2020
(86) PCT No.: PCT/US2020/037447

§ 371 Date: Dec. 2, 2021

Related U.S. Application Data
(60) Provisional application No. 62/861,034, filed on Jun. 13, 2019.

(51) Int. Cl. C09K 13/06; H01L 21/311; H01L 21/3213

(52) U.S. Cl. CPC C09K 13/06; H01L 21/31111; H01L 21/32134

(57) ABSTRACT

Described herein is an etching solution suitable for the selective removal of silicon over p-doped silicon and/or silicon-germanium from a microelectronic device, having water; at least one of NH₄OH or a quaternary ammonium hydroxide; at least one compound selected from benzoquinone or a derivative of benzoquinone; quinoline or a derivative of quinoline; an unsubstituted or substituted C₆₋₂₀ aliphatic acid; a C₄₋₁₂ alkylamine; and a polyalkylenimine; optionally at least one water-miscible organic solvent; and optionally, at least one compound selected from an alkanolamine and a polyamine.

### BACKGROUND OF THE INVENTION

The present invention relates to liquid etching compositions used in the manufacture of semiconductor devices. More specifically, the invention provides an etching composition that exhibits increased etch selectivity of polysilicon over p-doped silicon and silicon-germanium during the manufacture of a composite semiconductor device.

Semiconductors have been continuously improved in performance, costs and power consumption by miniaturization by integration scaling according to technology roadmap. To continue to achieve the scaling of transistors to meet future requirements, the gate thickness of transistors using a conventional gate insulating film made of silicon oxide becomes excessively small, so that a leakage current owing to a tunnel current increases, and power consumption becomes large. Moreover, in recent years, there is an increasing demand for mobile equipment using semiconductor devices such as mobile phones, notebook type personal computers and potable music players. In this case, a power supply for such mobile equipment has been frequently relied upon rechargeable batteries. Therefore, it has been required that the semiconductor devices used in the mobile equipment have a low power consumption to achieve long-term use thereof. As a result, for the purpose of reducing a leakage current during a stand-by state of the equipment, a technique has been proposed to combine an insulating material and a gate electrode as constituents of a transistor, wherein a high dielectric material and a metal gate are used in place of the conventional combination of silicone oxide and polysilicon.

One method of producing the high dielectric material and the metal gate is referred to as a gate-last method in which after producing a transistor using combination of a high dielectric material and polysilicon, the polysilicon is removed to replace it with a metal gate. When the dummy polysilicon gate is removed by an alkaline wet chemical process, the gate oxide will be exposed to the alkaline formulation. Because the gate oxide layer is thin (typically around 10-30 Å), there is a strong potential that the wet chemistry can penetrate through the gate oxide and create pit defects in the p-doped silicon if the gate oxide is not well protected. For this reason, if an etching amount of the polysilicon per unit time (hereinafter referred to as an “etch rate”) is small, the time required for the etching tends to be prolonged and risk for corrosion of the oxide layer is increased. Conventional polysilicon wet etching chemistry typically employs etchants like NH₄OH or TMAH that exhibit decent polysilicon removal power, however, the etch rate on gate oxides such as, for example, silicon oxide, is a concern when the device design gets smaller. Minimizing oxide loss in a dummy gate removal process becomes critical for success for advanced technology nodes. Besides minimizing oxide loss, another important approach to prevent the pit defects in the p-doped silicon is to lower p-doped silicon etch rates to reach high selectivity of polysilicon over p-doped silicon. Similar to selective etch of polysilicon over p-doped silicon, when silicon-germanium is used, high selectivity of polysilicon over silicon-germanium is also needed.

Accordingly, there is a need in the art for a wet chemistry formulation that has a very high etch rate for polysilicon and that significantly prevents the etching of a p-doped silicon and/or silicon-germanium layer or any other metal, side wall, and interlayer insulating films that may also be exposed to such wet chemistry.

### SUMMARY

To solve the above problem, a highly selective formulation for etching polysilicon over p-doped silicon and/or for etching polysilicon over silicon-germanium is required. Such wet chemical compositions are disclosed herein. In one aspect disclosed herein are etching solutions suitable for the selective removal of polysilicon over p-doped silicon and/or silicon germanium alloy from a microelectronic device, which comprise water; at least one of NH₄OH or a quaternary ammonium hydroxide; at least one compound selected from benzoquinone or a derivative of benzoquinone; quinoline or a derivative of quinoline; an unsubstituted or substituted C₆₋₂₀ aliphatic acid; a C₄₋₁₂ alkylamine and a polyalkylenimine, and mixtures thereof; optionally at least one water-miscible organic solvent; and optionally, at least one compound selected from the group consisting of an alkanolamine and a polyamine, and mixtures thereof; and optionally a fluoride ion source.

In another aspect, disclosed herein are etching solutions suitable for the selective removal of polysilicon over p-doped silicon and/or silicon germanium from a microelectronic device, which comprise, consist essentially of or consist of water; at least one water-miscible organic solvent; at least one of NH₄OH or a quaternary ammonium hydroxide; at least one compound selected from the group consisting of an alkanolamine and a polyamine; optionally, at least one compound selected from the group consisting of a C₄₋₁₂ alkylamine, a polyalkylenimine, and a C₆₋₂₀ mercapto carboxylic acid (or C₆₋₂₀ aliphatic acid compound); optionally, at least one fluoride ion source; at least one benzoquinone or derivatives of benzoquinone; optionally, a quinoline or derivative of quinoline; and optionally, a surfactant.

In another aspect, the present invention provides methods of selectively enhancing the etch rate of polysilicon relative to p-doped silicon and/or polysilicon relative to silicon germanium on a composite semiconductor device comprising polysilicon and p-doped silicon and/or silicon germanium, the method comprising the steps of: contacting the composite semiconductor device comprising polysilicon and p-doped silicon and/or silicon germanium with an aqueous composition comprising water; at least one of NH₄OH or a quaternary ammonium hydroxide; at least one compound selected from benzoquinone or a derivative of benzoquinone, quinoline or a derivative of quinoline; an unsubstituted or substituted C₆₋₂₀ aliphatic acid; a C₄₋₁₂ alkylamine and a polyalkylenimine, and mixtures thereof; optionally at least one water-miscible organic solvent; and optionally, at least one compound selected from the group consisting of an alkanolamine and a polyamine, and mixtures thereof; and optionally a fluoride ion source; and rinsing the composite semiconductor device after the silicon is at least partially removed.

In another aspect, the present invention provides methods of selectively enhancing the etch rate of polysilicon relative to p-doped silicon and/or polysilicon relative to silicon-germanium on a composite semiconductor device comprising polysilicon and p-doped silicon and/or silicon germanium, the method comprising the steps of: contacting the composite semiconductor device comprising polysilicon and p-doped silicon and/or silicon germanium with an aqueous composition comprising water; at least one water-miscible organic solvent; at least one of NH₄OH or a quaternary ammonium hydroxide; at least one compound selected from the group consisting of an alkanolamine and a polyamine; optionally, at least one compound selected from the group consisting of a C₄₋₁₂ alkylamine, a polyalkylenimine, and a mercapto carboxylic acid (or a C₆₋₂₀ aliphatic acid compound); optionally, at least one fluoride ion source; at least one benzoquinone or derivatives of benzoquinone; optionally, a quinoline or derivative of quinoline; optionally, a surfactant; and optionally a fluoride ion source; and rinsing the composite semiconductor device after the silicon is at least partially removed.

Embodiments disclosed herein can be used alone or in combinations with each other.

### DETAILED DESCRIPTION

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention. The use of the term “comprising” in the specification and the claims includes the more narrow language of “consisting essentially of” and “consisting of”.

Embodiments of this invention are described herein, including the best mode known to the inventors for carrying out the invention. Variations of those embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

The present invention relates generally to compositions useful for the selective removal of silicon over p-doped silicon and/or selective removal of silicon over silicon-germanium from a microelectronic device having such material(s) thereon during its manufacture.

It will be understood that the term “silicon” such as, for example, “p-doped silicon,” as deposited as a material on a microelectronic device will include polysilicon.

For ease of reference, “microelectronic device” corresponds to semiconductor devices or substrates, wafers, flat panel displays, phase change memory devices, solar panels and other products including solar substrates, photovoltaics, and microelectromechanical systems (MEMS), manufactured for use in microelectronic, integrated circuit, or computer chip applications. Solar substrates include, but are not limited to, silicon, amorphous silicon, polycrystalline silicon, monocrystalline silicon, CdTe, copper indium selenide, copper indium sulfide, and gallium arsenide on gallium. The solar substrates may be doped or undoped. It is to be understood that the term “microelectronic device” or “semiconductor device” or “semiconductor substrate” is not meant to be limiting in any way and includes any substrate that will eventually become a microelectronic device or microelectronic assembly. The term “composite” to describe a semiconductor device or substrate means that the device or substrate comprises at least two or more different materials forming layers or electronic structures thereon. Such materials may include metals, metal alloys, low-k dielectric materials, barrier materials, and other layers and materials know to a person of skill.

As defined herein, “low-k dielectric material” corresponds to any material used as a dielectric material in a layered microelectronic device, wherein the material has a dielectric constant less than about 3.5. Preferably, the low-k dielectric materials include low-polarity materials such as silicon-containing organic polymers, silicon-containing hybrid organic/inorganic materials, organosilicate glass (OSG), TEOS, fluorinated silicate glass (FSG), silicon dioxide, and carbon-doped oxide (CDO) glass. It is to be appreciated that the low-k dielectric materials may have varying densities and varying porosities.

“Substantially free” is defined herein as less than 0.001 wt. %. “Substantially free” also includes 0.000 wt. %. The term “free of” means 0.000 wt. %.

As used herein, “about” is intended to correspond to ±5% of the stated value.

In all such compositions, wherein specific components of the composition are discussed in reference to weight percentage ranges including a zero lower limit, it will be understood that such components may be present or absent in various specific embodiments of the composition, and that in instances where such components are present, they may be present at concentrations as low as 0.001 weight percent, based on the total weight of the composition in which such components are employed. The total weight percent for the composition is 100%.

In the broad aspect, the etching solution of the present development comprises an etching solution suitable for the selective removal of polysilicon over p-doped silicon and/or polysilicon over silicon germanium alloy from a microelectronic device, comprising, consists essentially of, or consists of water; at least one of NH₄OH or a quaternary ammonium hydroxide; at least one compound selected from benzoquinone or a derivative of benzoquinone, quinoline or a derivative of quinoline; an unsubstituted or substituted C₆₋₂₀ aliphatic acid; a C₄₋₁₂ alkylamine and a polyalkylenimine, and mixtures thereof; optionally at least one water-miscible organic solvent; optionally, at least one compound selected from the group consisting of an alkanolamine and a polyamine, and mixtures thereof; and optionally a fluoride ion source.

In another the broad aspect, the etching solution of the present development comprises an etching solution suitable for the selective removal of polysilicon over p-doped silicon and/or polysilicon over silicon germanium alloy from a microelectronic device, comprising, consisting essentially of, or consisting of water; at least one water-miscible organic solvent; at least one of NH₄OH or a quaternary ammonium hydroxide; at least one compound selected from the group consisting of an alkanolamine and a polyamine; optionally, at least one compound selected from the group consisting of a C₄₋₁₂ alkylamine, a polyalkylenimine, and a mercapto carboxylic acid (or a C₆₋₂₀ aliphatic acid compound); optionally, at least one fluoride ion source; at least one benzoquinone or derivatives of benzoquinone; optionally, a quinoline or derivative of quinoline; and optionally, a surfactant.

The compositions of the present invention are suitable for use in a process for making a gate all around structure on an electronic device. Such processes are known in the art such as, for example, the process disclosed in U.S. patent application Publication No. 2017/0179248, U.S. patent application Publication No. 2017/0104062, U.S. patent application Publication No. 2017/0133462, and U.S. patent application Publication No. 2017/0040321, the disclosures of which are incorporated herein by reference.

The etching compositions disclosed herein exhibit excellent polysilicon removal preferentially over p-doped silicon and/or polysilicon over silicon-germanium in, for example, the removal of a dummy gate made of polysilicon in a process for producing, for example, a transistor using a structural body which includes a substrate, and a dummy gate laminate formed by laminating at least a high dielectric material film and the dummy gate made of polysilicon, a side wall disposed to cover a side surface of the laminate and an interlayer insulating film disposed to cover the side wall which are provided on the substrate, in which the dummy gate is replaced with a metal gate containing hafnium, zirconium, titanium, tantalum or tungsten.

The etching compositions disclosed herein are aqueous-based and, thus, comprise water. In the present invention, water functions in various ways such as, for example, to dissolve one or more components of the composition, as a carrier of the components, as an aid in the removal of residue, as a viscosity modifier of the composition, and as a diluent. Preferably, the water employed in the etching composition is de-ionized (DI) water. The ranges of water described in the next paragraph include all of the water in the composition from any source.

It is believed that, for most applications, the total weight percent of water in the composition (i.e., from all sources) will be present in a range with start and end points selected from the following group of numbers: 0.5, 1, 5, 10, 15, 17, 20, 23, 25, 30, 35, 40, 45, 50, 55, 60, 65, 70, 75, 80, 82, 85, 88, 89, 90, 91, 92, 93, 94, 95, 96, 97, 98, 98.6, 98.8, 98.9, 99, 99.3, 99.5, 99.6, 99.7, 99.8 and 99.9. Examples of the ranges of water that may be used in the composition include, for examples, from about 0.5% to about 99.9% by wt, or from about 15% to about 99.9% by wt, or from about 0.5% to about 60% by wt., or 1% to about 60% by wt. of water; or from about 0.5% to about 40% by wt., or from about 1% to about 25% by wt., or from about 1% to about 20% by wt., or from about 1% to about 15% by wt.; or from about 5% to about 20% by wt.; or from 5% to about 15% by wt. or from 20% to about 60% by wt., or from 25% to about 60% by wt. or from about 30% to about 60% by wt., or from about 35% to about 55% by wt.; or from about 15% to about 30% by wt.; or from about 5% to about 35% by wt.; or from about 10% to about 20% by wt. of water. Still other preferred embodiments of the present invention may include water in an amount to achieve the desired weight percent of the other ingredients. In other embodiments, for examples in embodiments of the solutions of this invention that comprise low amounts or are substantially free of or are free of water-miscible solvents therein and/or comprise low amounts or are substantially free of or are free of alkanolamines and/or polyamines, the total weight percent of water in the composition (i.e., from all sources) may be present in a range with start and end points selected from the following group of numbers: 70, 75, 80, 82, 85, 88, 89, 90, 91, 92, 93, 94, 95, 96, 97, 98, 98.6, 98.8, 98.9, 99, 99.3, 99.5, 99.6, 99.7, 99.8 and 99.9. Examples of the ranges of water that may be used in the composition include, for examples, from about 70% to about 99.9% by wt., or 80% to about 99.9% by wt. of water; or from about 85% to about 99.9% by wt. of water, or from about 88% to about 99.9% by wt. of water, or from about 90% to about 99.9% by wt., or from about 95% to about 99.9% by wt., or from about 97% to about 99.9% by wt. of water.

The etching compositions disclosed herein comprise a silicon etchant that is at least one of an ammonium compound selected from the group consisting of a quaternary ammonium hydroxide and ammonium hydroxide. In embodiments, the pH of the resulting etching solution comprising at least one of an ammonium compound selected from the group consisting of a quaternary ammonium hydroxide and ammonium hydroxide is from about 7.5 to 14, or from about 9.0 to 14, or from about 10 to 14, or from about 11 to 14, or from about 12 to 14 or from about 13 to 14, or above 13.

The quaternary ammonium hydroxide may be a quaternary ammonium hydroxide in which all of the alkyl groups are the same, such as, tetramethylammonium hydroxide, tetraethylammonium hydroxide, tetrapropylammonium hydroxide, and/or tetrabutylammonium hydroxide and so on.

Alternatively and preferred are quaternary ammonium hydroxides including tetraalkylammonium hydroxides wherein not all of the alkyl groups are the same. Examples of tetraalkylammonium hydroxides wherein not all of the alkyl groups are the same include the group consisting of benzyltrimethyl ammonium hydroxide, ethyltrimethyl ammonium hydroxide (ETMAH), 2-hydroxyethyltrimethyl ammonium hydroxide, benzyltriethyl ammonium hydroxide, hexadecyltrimethyl ammonium hydroxide, methyltriethylammonium hydroxide and mixtures thereof.

The amount of the quaternary ammonium hydroxide compound or ammonium hydroxide in the composition will, for the most applications, comprise weight percents within a range having start and end points selected from the following group of numbers: 0.5, 1, 2, 3, 5, 7, 8, 10, 12, 15, 20, 25, 30 and 35. Examples of ranges of quaternary ammonium hydroxide or ammonium hydroxide in the compositions of this invention may be from about 1% to about 35%, or from about 1% to about 20%, or from about 1% to about 10% by weight of the composition, specifically, about 8% to about 35% by weight of the composition, or more specifically, about 20% to about 35% by weight of the composition. By way of example, if the quaternary ammonium hydroxide compound is an ETMAH (20% solution), then if added at 25% by weight, there will be 5% active quaternary ammonium hydroxide compound; or stated differently, 5% quaternary ammonium hydroxide added on a neat basis. In some embodiments, the at least one quaternary ammonium hydroxide compound (on a neat basis) and/or the ammonium hydroxide (on a neat basis) comprise weight percents within a range having start and end points selected from the following group of numbers: 0.05, 0.1, 0.2, 0.3, 0.4, 0.5, 0.8, 1, 1.5, 2, 2.5, 3, 4, 5, 6, 7, 8, 9, 10, 11, 12, 14, 15, 17, 20, 25, 30 and 35. Examples of ranges of ammonium hydroxide (neat) and/or the at least one quaternary ammonium hydroxide (neat) in the compositions of this invention may be from about 0.2% to about 15% weight percent, or from about 0.3 to about 12%, or from about 0.05 to about 7%, or from about 0.1 to about 10%, or from about 0.1 to about 12%, or from about 0.1 to about 7%, or from about 0.5 to about 7%, or from about 0.05% to about 15%, or from about 0.05% to about 8% or from about 0.05 to about 5%, or from about 0.1 to about 5%, or from about 0.2 to about 5% or from about 0.05% to about 10%, or from about 3 to about 12% by weight of the composition.

In some embodiments, the etching compositions disclosed herein also (with the water and the quaternary ammonium hydroxide compound or ammonium hydroxide) comprise at least one compound selected from, or selected from the group consisting of benzoquinone or derivatives of benzoquinone, quinoline or derivatives of quinoline; unsubstituted or substituted C₆₋₂₀ aliphatic acid compounds, C₄₋₁₂ alkylamines, and polyalkylenimines and mixtures thereof. In alternative embodiments, the etching compositions disclosed herein also (with the water and the quaternary ammonium hydroxide compound or ammonium hydroxide) comprise at least one compound selected from, or selected from the group consisting of benzoquinone or derivatives of benzoquinone, quinoline or derivatives of quinoline; and unsubstituted or substituted C₆₋₂₀ aliphatic acid compounds and mixtures thereof. In alternative embodiments, the etching compositions disclosed herein also comprise (with the water and the quaternary ammonium hydroxide compound or ammonium hydroxide) at least one compound selected from, or selected from the group consisting of C₄₋₁₂ alkylamine, and polyalkylenimine, and mixtures thereof. In alternative embodiments, the etching compositions disclosed herein also comprise (with the water and the quaternary ammonium hydroxide compound or ammonium hydroxide) at least one compound selected from, or selected from the group consisting of benzoquinone or derivatives of benzoquinone and quinoline or derivatives of quinoline and mixtures thereof. In alternative embodiments, the etching compositions disclosed herein comprise (with the water and the quaternary ammonium hydroxide compound or ammonium hydroxide) at least one benzoquinone or derivatives of benzoquinone and at least one quinoline or derivative of quinoline. In alternative embodiments, the etching compositions disclosed herein comprise (with the water and the quaternary ammonium hydroxide compound or ammonium hydroxide) at least one benzoquinone or derivatives of benzoquinone. In an embodiment comprising the at least one benzoquinone or derivatives of benzoquinone (with the water and the quaternary ammonium hydroxide compound or ammonium hydroxide), the compositions may further comprise at least one compound selected from, or selected from the group consisting of quinoline or derivatives of quinoline; unsubstituted or substituted C₆₋₂₀ aliphatic acid compounds, C₄₋₁₂ alkylamines, and polyalkylenimines, and mixtures thereof. In an embodiment comprising the at least one benzoquinone or derivatives of benzoquinone (with the water and the quaternary ammonium hydroxide compound or ammonium hydroxide), the compositions may further comprise at least one compound selected from, or selected from the group consisting of water miscible organic solvents and/or alkanolamines and/or polyamines and mixtures thereof.

Examples of benzoquinone or a derivative of benzoquinone, useful in the compositions of this invention, include 1,4-benzoquinone, o-benzoquinone, 2-methyl-1,4-benzoquinone, 2,5-dihydroxyl-p-benzoquinone, and 2-tert-butyl-1,4-benzoquinone, 2-phenyl-1,4-benzoquinone, 2-methoxy-1,4-benzoquinone; 2,6-dimethyl-1,4-benzoquinone; 2,3-dimethyl-1,4-benzoquinone; trimethyl-1,4-benzoquinone; 2,6-dimethoxy-1,4-benzoquinone; tetramethyl-1,4-benzoquinone; tetrafluoro-1,4-benzoquinone; 2,5-dichloro-1,4-benzoquinone; Tetrachloro-1,4-benzoquinone; 2-chloro-1,4-benzoquinone; 1,4-naphthoquinone; 9,10-Anthraquinone; 1,8-dichloro-9,10-anthraquinone; 2,3-dichloro-1,4-naphthoquinone; 3,5-di-tert-butyl-1,2-benzoquinone; 4-tert-butyl-1,2-benzoquinone; Phenanthrenequinone; 1,2-naphthoquinone; 1,10-phenanthroline-5,6-dione; tetrachloro-1,2-benzoquinone. The benzoquinone or a derivative of benzoquinone may be selected from p-benzoquinone, o-benzoquinone, 2-methyl-p-benzoquinone, 2,5-dihydroxyl-p-benzoquinone, and 2-t-butyl-p benzoquinone. The benzoquinone, if present, in the etching composition primarily functions as an inhibitor.

Examples of quinoline or derivatives of quinoline, useful in the compositions of this invention, include quinoline, 8-hydroxy quinoline, 2-methyl-8-hydroxyquinoline and aminoquinoline. The quinoline(s) in the composition provide protection for the silicon-germanium alloy when it is present on the substrate. The quinolines, therefore, may be optional components in the compositions of this invention. In some embodiments, the quinolines may be selected from 8-hydroxy quinoline and 2-methyl-8-hydroxyquinoline.

In some embodiments the compositions of this invention will be free of, or substantially free of, any or all quinoline and/or quinoline derivatives and/or any of the above-listed examples of the quinolines in any combination, especially when the Si-Ge is not present on the substrate.

The unsubstituted or substituted C₆₋₂₀ aliphatic acid compound may comprise one or more linear, branched or cyclic alkyl groups. The carboxylic acid group may be the only group on the C₆₋₂₀ aliphatic acid, making the C₆₋₂₀ aliphatic acid unsubstituted. The carboxylic acid group may be a terminal group on a linear, branched or cyclic alkyl group or may be located within a linear, branched or cyclic alkyl group. If there is more than one group present on the C₆₋₂₀ aliphatic acid compound, there may be a group present on each of the terminal carbons on opposite ends of a linear alkyl chain or alternatively one or more of the substituent group may be located within an alkyl group (within a carbon chain). The substituent group may be within of a linear, branched or cyclic group. The C₆₋₂₀ aliphatic acid may comprise one or more substituent groups (in addition to the carboxylic acid group), including one or more other carboxylic acid groups, thiol groups, hydroxyl groups, or amino groups. Examples of unsubstituted C₆₋₂₀ aliphatic acid compounds useful in the compositions of this invention include hexanoic acid, heptanoic acid, octanoic acid, nonanoic acid, decanoic acid, undecanoic acid, dodecanoic acid, palmitic acid and oleic acid. Examples of the substituted C₆₋₂₀ aliphatic acid compounds useful in the composition of this invention include C₆₋₂₀ mercapto carboxylic acids, including 6-mercaptohexanoic acid, 7-mercaptoheptanoic acid, 8-mercaptooctanoic acid, 9-mercaptononanoic acid, 10-mercaptodecanoic acid, 11-mercaptoundecanoic acid, 12-mercaptododecanoic acid and 16-mercaptohexadecanoic acid. An example of a C₆₋₂₀ aliphatic acid substituted with a hydroxyl group, useful in the composition of this invention, is juniperic acid.

The preferred substituted or unsubstituted C₆₋₂₀ aliphatic acid compounds are substituted or unsubstituted C₆₋₁₆ or C₆₋₁₄ or C₈₋₁₄ aliphatic acid compounds. The presently preferred substituted C₆₋₂₀ aliphatic acid compounds are C₆₋₂₀ or C₆₋₁₆ or C₆₋₁₄ or C₈₋₁₄ mercapto carboxylic acids, such as, 10-mercaptodecanoic acid and 11-mercaptoundecanoic acid. The presently preferred unsubstituted C₆₋₂₀ or C₆₋₁₆ or C₆₋₁₄ or C₈₋₁₄ aliphatic acid compounds are decanoic acid, and undecanoic acid.

Examples of suitable C₄₋₁₂ alkylamines include hexylamine, surfactant salts of hexylamine, octylamine, surfactant salts of octylamine, decylamine, surfactant salts of decylamine, dodecylamine, and surfactant salts of dodecylamine. The C₄₋₁₂ alkylamine(s), when employed, function in part as p-doped silicon corrosion inhibitor.

The polyalkyleneimine, if present in the composition, may be a polyethyleneimine (PEI). Any PEI may be used, but it is preferred that a homopolymeric polyethyleneimine is employed. The PEI may be branched or linear, but preferably it is branched. The polyalkyleneimine when employed, functions in part as p-doped silicon corrosion inhibitor.

While it has been found that the polyalkyleneimine, or PEI used may have any formula weight for effectiveness, preferably the polyalkyleneimine, or PEI has a lower formula weight (FW). In certain embodiments, the polyalkyleneimine or the PEI may have a FW between 100 and 50,000, between 400 and 25,000, between 800 and 10,000, or between 1000 and 3000. Preferably the polyalkyleneimine or PEI has a weight average molecular weight between 100 and 2500, preferably 200 and 1500 and most preferably between 400 and 1200 or between 700 and 900. A molecular weight of 800 is particularly suitable. The molecular weight is suitably determined by light scattering techniques known in the art. Polyethyleneimines are commercially available, for example Lupasol® 800 which is supplied by BASF.

The etching compositions comprise at least one compound selected from, or selected from the group consisting of benzoquinone or derivatives of benzoquinone; quinoline or derivatives of quinoline; unsubstituted or substituted C₆₋₂₀ aliphatic acid compounds; C₄₋₁₂ alkylamines, and polyalkylenimines, or mixtures thereof. The amount of the at least one of those components or two or more of those components will be from about 0.01 to about 8, or from about 0.05% to about 6%, or from about 0.1% to about 5%, or from about 0.1% to about 3%, or from about 0.2% to about 3% or from 0.001 to about 10%, or from 0.001 to about 5%, or from about 0.001 to about 3%, or from about 0.001 to about 1%, or from about 0.2% to about 1% by weight of the composition. Any of those components, alone or together in the etching composition of this invention may be present in the composition in a weight percent amount within a range having start and end points selected from the following group of numbers: 0.001, 0.01, 0.03, 0.05, 0.07, 0.1, 0.2, 0.5, 0.7, 1, 1.5, 2, 2.5, 3, 3.5, 4, 4.5, 5, 5.5, 6, 6.5, 7, 7.5 8, 8.5, 9, 9.5, and 10.

Alternatively, the amount of the at least one selected from benzoquinone or derivatives of benzoquinone; quinoline or derivatives of quinoline; and unsubstituted or substituted 06-20 aliphatic acid compounds, or mixtures thereof present in the composition may be in a weight percent amount within a range having start and end points selected from the following group of numbers: 0.001, 0.01, 0.03, 0.05, 0.07, 0.1, 0.2, 0.5, 0.7, 1, 1.5, 2, 2.5, 3, 3.5, 4, 4.5, 5, 5.5, 6, 6.5, 7, 7.5, 8. For examples, the amount of the at least one of benzoquinone, derivatives of benzoquinone; quinoline, derivatives of quinoline; unsubstituted or substituted C₆₋₂₀ aliphatic acid compounds or mixtures of those components may be from about 0.01 to about 8, or from about 0.05% to about 6%, or from about 0.1% to about 5%, or from about 0.1% to about 3%, or from about 0.2% to about 3%, or from 0.001 to about 10%, or from 0.001 to about 5%, or from about 0.001 to about 3%, or from about 0.001 to about 1%, or from about 0.2% to about 1% by weight of the composition.

If the etching compositions comprise at least one compound selected from benzoquinone or derivatives of benzoquinone; quinoline or derivatives of quinoline; or mixtures thereof, the amount of the at least one of those added components or two or more of those components will be from about 0.01 to about 8, or from about 0.05% to about 6%, or from about 0.1% to about 5%, or from about 0.1% to about 3%, or from about 0.2% to about 3% or from 0.001 to about 10%, or from 0.001 to about 5%, or from about 0.001 to about 3% from about 0.001 to about 1%, or from about 0.2% to about 1% by weight of the composition. Alternatively the amount of the at least one of benzoquinone or derivatives of benzoquinone; quinoline or derivatives of quinoline; and mixtures thereof may be present in the composition in a weight percent amount within a range having start and end points selected from the following group of numbers: 0.001, 0.01, 0.03, 0.05, 0.07, 0.1, 0.2, 0.5, 0.7, 1, 1.5, 2, 2.5, 3, 3.5, 4, 4.5, 5, 5.5, 6, 6.5, 7, 7.5, 8, 8.5, 9, 9.5, and 10.

If the etching compositions comprise at least one compound selected from benzoquinone or derivatives of benzoquinone; or mixtures thereof, the amount of the at least one of those added components or two or more of those components will be from about 0.01 to about 8, or from about 0.05% to about 6%, or from about 0.1% to about 5%, or from about 0.1% to about 3%, or from about 0.2% to about 3%, or from 0.001 to about 10%, or from 0.001 to about 5%, or from about 0.001 to about 3%, or from about 0.001 to about 1%, or from about 0.2% to about 1% by weight of the composition. Alternatively, the amount of the at least one of benzoquinone or derivatives of benzoquinone or mixtures thereof may be present in the composition in a weight percent amount within a range having start and end points selected from the following group of numbers: 0.001, 0.01, 0.03, 0.05, 0.07, 0.1, 0.2, 0.5, 0.7, 1, 1.5, 2, 2.5, 3, 3.5, 4, 4.5, 5, 5.5, 6, 6.5, 7, 7.5, 8, 8.5, 9, 9.5, and 10.

If the etching compositions comprise at least one compound selected from C₄₋₁₂ alkylamines, and polyalkylenimines; or mixtures thereof, the amount of the at least one of those added components or two or more of those components will be from about 0.01 to about 8, or from about 0.05% to about 6%, or from about 0.1% to about 5%, or from about 0.1% to about 3%, or from about 0.2% to about 3%, or from 0.001 to about 10%, or from 0.001 to about 5%, or from about 0.001 to about 3%, or from about 0.001 to about 1%, or from about 0.2% to about 1% by weight of the composition. Alternatively, the amount of the at least one of C₄₋₁₂ alkylamines, and polyalkylenimines, or mixtures thereof may be present in the composition in a weight percent amount within a range having start and end points selected from the following group of numbers: 0.001, 0.01, 0.03, 0.05, 0.07, 0.1, 0.2, 0.5, 0.7, 1, 1.5, 2, 2.5, 3, 3.5, 4, 4.5, 5, 5.5, 6, 6.5, 7, 7.5, 8, 8.5, 9, 9.5, and 10.

In an alternative embodiment, the C₄₋₁₂ alkylamine, if employed with any of the other components in any of the compositions of this invention, may comprise less than 5% by weight of the composition, preferably less than 1.5% by weight, preferably less than 0.25% by weight of the composition and most preferably less than or equal to 0.2% by weight of the composition. In some embodiments, the mercapto carboxylic acid, if employed in any of the compositions of this invention, may comprise less than 5% by weight of the composition, preferably less than 1.5% by weight, preferably less than 0.25% by weight of the composition. In some embodiments, if employed in any of the compositions of this invention, the polyalkyleneimine may comprise a polyethyleneimine (PEI) and preferably the PEI comprises from 0.001 to about 5% by weight of the composition, preferably from 0.001 to about 1.5% by weight, preferably from 0.001 to about 0.25% by weight of the composition and most preferably from 0.001 to about 0.2% by weight of the composition, if employed.

Alternatively, in some embodiments, the compositions may be substantially free of or free of one or more of: C₄₋₁₂ alkylamines and/or polyalkylenimines, and/or C₆₋₂₀ aliphatic acid compounds and/or 06-20 mercapto carboxylic acids and/or any of the individual compounds listed as examples of each listed above in any combination. Alternatively, in other embodiments, the compositions may be substantially free of or free of one or more of: benzoquinone and/or derivatives of benzoquinone, and/or quinoline and/or derivatives of quinoline and/or any of the individual compounds listed as examples of benzoquinone and/or derivatives of benzoquinone, and/or quinoline and/or derivatives of quinoline listed above in any combination.

In some embodiments, the etching compositions disclosed herein may also comprise at least one selected from, or selected from the group consisting of an alkanolamine and a polyamine compound and mixtures thereof in any combination with, or without, any of the other components above. For some embodiments the alkanolamine and/or a polyamine compound are optional components.

Suitable alkanolamine compounds, if present in the compositions of this invention, include the lower alkanolamines which are primary, secondary and tertiary having from 1 to 5 carbon atoms. Examples of such alkanolamines include N-methylethanolamine (NMEA), monoethanolamine (MEA), diethanolamine, monoisopropanolamine, diisopropanolamine and triisopropanolamine, 2-(2-aminoethylamino)ethanol, 2-(2-aminoethoxy)ethanol, triethanolamine, N-ethyl ethanolamine, N,N-dimethylethanolamine, N,N-diethyl ethanolamine, N-methyl diethanolamine, N-ethyl diethanolamine, cyclohexylaminediethanol, and mixtures thereof.

In some embodiments, if present, the alkanolamine may be selected from or selected from the group consisting of triethanolamine (TEA), diethanolamine, N-methyl diethanolamine, monoisopropanolamine, diisopropanolamine, monoethanolamine, amino(ethoxy) ethanol (AEE), N-methyl ethanolamine, monoisopropanolamine, cyclohexylaminediethanol, and mixtures thereof.

Suitable polyamine compounds, if present, include pentamethyldiethylenetriamine (PMDETA), triethylenediamine (TEDA), triethylenetetramine (TETA), tetramethylethylenediamine (TMEDA), and diethylenetriamine (DETA).

The amount of the alkanolamine or polyamine compound, if present in the compositions may comprise weight percents within a range having start and end points selected from the following group of numbers: 0.5, 1, 2, 3, 5, 7, 8, 10, 12, 15, 20, 25, 30, 35, 40, 45, 50, 55, 60, 65 and 70. Examples of ranges of at least one alkanolamine or polyamine compound(s) in the compositions of this invention may be comprise from about 1% to about 50% by weight of the composition, or about 8% to about 50% by weight of the composition, or about 20% to about 50% by weight of the composition. In some embodiments, the at least one alkanolamine or polyamine compound(s) comprises from about 20% to about 65% weight percent or, from about 10 to about 60%, or from about 15 to about 55%, or from about 20 to about 50%, or from about 1 to about 12%, or from about 5 to about 40%, or from about 25 to about 45%, or from about 30 to about 40% by weight of the composition. In some embodiments, the compositions of this invention may be substantially free of, or free of, alkanolamines and/or polyamines or any of the individual examples of alkanolamines and/or polyamines listed above, alone or in any combination.

Certain embodiments of the etching compositions disclosed herein may also comprise a water-miscible organic solvent in any combination with, or without, at least some of the components listed above. Examples of water-miscible organic solvents that can be employed are ethylene glycol, propylene glycol, 1,4-butanediol, tripropylene glycol methyl ether, propylene glycol propyl ether, diethylene gycol n-butyl ether (BDG) (e.g., commercially available under the trade designation Dowanol® DB), dipropylene glycol methyl ether (DPM) hexyloxypropylamine, poly(oxyethylene)diamine, dimethylsulfoxide (DMSO), tetrahydrofurfuryl alcohol, glycerol, alcohols, sulfolane, triethyl phosphate, and mixtures thereof. Preferred solvents are alcohols, diols, or mixtures thereof. Most preferred solvents are selected from the group consisting of sulfolane, DMSO, ethylene glycol, glycerol, dipropylene glycol monomethyl ether, and propylene glycol.

For embodiments comprising the water-miscible organic solvent, the amount of water-miscible organic solvent, if present in the composition may be in a range having start and end points selected from the following list of weight percents: 0.5, 1, 5, 7, 10, 12, 15, 20, 25, 29, 30, 33, 35, 40, 44, 50, 55, 59.5, 65 and 70. Examples of such ranges of solvent include from about 0.5% to about 70% by weight; or from about 0.5% to about 59.5% by weight; or from about 1% to about 50% by weight; or from about 1% to about 40% by weight; or from about 0.5% to about 30% by weight; or from about 30% to about 70% by weight; or from about 1% to about 30% by weight; or from about 5% to about 30% by weight; or from about 5% to about 20% by weight; or from about 7% to about 20%, or from about 10% to about 30% by weight; or from about 15% to about 25% by weight of the composition. In alternative embodiments, the compositions of this invention may be substantially free of, or free of, water-miscible solvents or any of the classes of, or individual solvents listed above, alone or in any combination.

The etching compositions disclosed herein optionally comprise one or more sources of fluoride ion, in any combination with, or without, at least some of the other components above. Fluoride ion functions principally as an auxiliary p-doped silicon corrosion inhibitor. Typical compounds that provide a fluoride ion source according to the present invention are hydrofluoric acid, ammonium fluoride, quaternary ammonium fluorides such as, for example, fluoroborates, fluoroboric acid, tetrabutylammonium tetrafluoroborate, aluminum hexafluoride, and a fluoride salt of an aliphatic primary, secondary or tertiary amine having the formula:

R¹NR²R³R⁴F,

wherein R¹, R², R³ and R⁴ individually represent H or a (C₁-C₄) alkyl group. Typically, the total number of carbon atoms in the R¹, R², R³ and R⁴ groups is 12 carbon atoms or less. Examples of fluoride salts of an aliphatic primary, secondary or tertiary amine such as, for example, tetramethylammonium fluoride, tetraethylammonium fluoride, methyltriethylammonium fluoride, and tetrabutylammonium fluoride.

It is believed that the amount of the compound used as the source of the fluoride ion in the etching composition will, for most applications, comprise, about 0.01 to about 8% by weight or from about 0.01 to about 7% by weight of a solution 40% ammonium fluoride, or stoichiometric equivalent thereof. Preferably, the compound comprises from about 0.02 to about 8% by weight, more preferably from about 0.02 to about 6% by weight, still more preferably, about 1 to about 8% by weight, and most preferably, from about 0.025% to about 5% by weight of a solution of about 40% ammonium fluoride. In some embodiments, the composition will comprise about 0.01 to about 8% by weight or about 0.01 to about 7% by weight of a fluoride ion source, which may be provided by a 40% ammonium fluoride solution. Preferably, the compound comprises from about 0.02 to about 6% by weight of a fluoride ion source and, most preferably, from about 0.025% to about 5% or from about 0.04 to about 2.5% by weight of a fluoride ion source or from about 0.05 to about 15% by weight of a solution of 40% ammonium fluoride, most preferably, from about 0.0625% to about 12.5% or from about 0.1 to about 6.25% by weight of a solution of 40% ammonium fluoride.

Alternatively, in some embodiments, the compositions will be substantially free of or free of one or more of any or all of the sources of fluoride ion (fluoride-containing compounds) and/or any of the individual examples of the sources of fluoride ion (fluoride-containing compounds) listed above in any combination.

The etching compositions disclosed herein may optionally comprise at least one surfactant in any combination with, or without, the other components above. The surfactant, when employed, functions in part to protect the silicon-germanium from etching. Surfactants for use in the compositions described herein include, but are not limited to, amphoteric salts, cationic surfactants, anionic surfactants, zwitterionic surfactants, non-ionic surfactants, and combinations thereof including, but not limited to, bis(2-ethylhexyl)phosphate, perfluoroheptanoic acid, prefluorodecanoic acid, trifluoromethanesulfonic acid, phosphonoacetic acid, dioctadecyl hydrogen phosphate, octadecyl dihydrogen phosphate, dodecenylsuccinic acid monodiethanol amide, 12 hydroxystearic acid, and dodecyl phosphate.

Non-ionic surfactants contemplated include, but are not limited to, polyoxyethylene lauryl ether (Emalmin NL-100 (Sanyo), Brij 30, Brij 98, Brij 35), dodecenylsuccinic acid monodiethanol amide (DSDA, Sanyo), ethylenediamine tetrakis(ethoxylate-block-propoxylate) tetrol (Tetronic 90R4), polyethylene glycols (e.g., PEG 400), polypropylene glycols, polyethylene or polypropylene glycol ethers, block copolymers based on ethylene oxide and propylene oxide (Newpole PE-68 (Sanyo), Pluronic L31, Pluronic 31R1, Pluronic L61, Pluronic F-127), polyoxypropylene sucrose ether (SN008S, Sanyo), t-octylphenoxypolyethoxyethanol (Triton X100), 10-ethoxy-9,9-dimethyldecan-1-amine (TRITON® CF-32), Polyoxyethylene (9) nonylphenylether, branched (IGEPAL CO-250), polyoxyethylene (40) nonylphenylether, branched (IGEPAL CO-890), polyoxyethylene sorbitol hexaoleate, polyoxyethylene sorbitol tetraoleate, polyethylene glycol sorbitan monooleate (Tween 80), sorbitan monooleate (Span 80), a combination of Tween 80 and Span 80, alcohol alkoxylates (e.g., Plurafac RA-20), alkyl-polyglucoside, ethyl perfluorobutyrate, 1,1,3,3,5,5-hexamethyl-1,5-bis[2-(5-norbornen-2-yl)ethyl]trisiloxane, monomeric octadecylsilane derivatives such as SIS6952.0 (Siliclad, Gelest), siloxane modified polysilazane such as PP1-SG10 Siliclad Glide 10 (Gelest), silicone-polyether copolymers such as Silwet L-77 (Setre Chemical Company), Silwet ECO Spreader (Momentive), and ethoxylated fluorosurfactants (ZONYL® FSO-100, ZONYL® FSN-100).

Cationic surfactants contemplated include, but are not limited to, cetyl trimethylammonium bromide (CTAB), heptadecanefluorooctane sulfonic acid, tetraethylammonium, stearyl trimethylammonium chloride (Econol TMS-28, Sanyo), 4-(4-diethylaminophenylazo)-1-(4-nitrobenzyl)pyridium bromide, cetylpyridinium chloride monohydrate, benzalkonium chloride, benzethonium chloride benzyldimethyldodecylammonium chloride, benzyldimethylhexadecylammonium chloride, hexadecyltrimethylammonium bromide, dimethyldioctadecylammonium chloride, dodecyltrimethylammonium chloride, hexadecyltrimethylammonium p-toluenesulfonate, didodecyldimethylammonium bromide, di(hydrogenated tallow)dimethylammonium chloride, tetraheptylammonium bromide, tetrakis(decyl)ammonium bromide, Aliquat® 336 and oxyphenonium bromide, guanidine hydrochloride (C(NH₂)₃Cl) or triflate salts such as tetrabutylammonium trifluoromethanesulfonate, dimethyldioctadecylammonium chloride, dimethyldihexadecylammonium bromide and di(hydrogenated tallow)dimethylammonium chloride (e.g., Arquad 2HT-75, Akzo Nobel).

Anionic surfactants contemplated include, but are not limited to, ammonium polyacrylate (e.g., DARVAN 821A), modified polyacrylic acid in water (e.g., SOKALAN CP10S), phosphate polyether ester (e.g., TRITON H-55), decylphosphonic acid, dodecylphosphonic acid (DDPA), tetradecylphosphonic acid, hexadecylphosphonic acid, octadecylphosphonic acid, dodecylbenzenesulfonic acid, poly(acrylic acid sodium salt), sodium polyoxyethylene lauryl ether, sodium dihexylsulfosuccinate, dicyclohexyl sulfosuccinate sodium salt, sodium 7-ethyl-2-methyl-4-undecyl sulfate (Tergitol 4), SODOSIL RM02, and phosphate fluorosurfactants such as Zonyl FSJ and ZONYL® UR.

Zwitterionic surfactants include, but are not limited to, acetylenic diols or modified acetylenic diols (e.g., SURFONYL® 504), cocamido propyl betaine, ethylene oxide alkylamines (AOA-8, Sanyo), N,N-dimethyldodecylamine N-oxide, sodium cocaminpropinate (LebonApl-D, Sanyo), 3-(N,N-dimethylmyristylammonio)propanesulfonate, and (3-(4-heptyl)phenyl-3-hydroxypropyl)dimethylammoniopropanesulfonate. Preferably, the at least one surfactant comprises dodecylbenzene sulfonic acid, dodecyl phosphonic acid, dodecyl phosphate, TRITON X-100, SOKALAN CP10S, PEG 400, and PLURONIC F-127.

When present, the amount of surfactant may be in a range from about 0.001 wt % to about 1 wt %, preferably about 0.1 wt % to about 1 wt %, based on the total weight of the composition. Alternatively, it is believed that for some applications, if present, the one or more surfactants will comprise from about 0.1 wt. % to about 15 wt. % of the composition; or from about 0.1 wt. % to about 10 wt. %, or from about 0.5 wt. % to about 5 wt. %, or from about 0.1 wt.% to about 1 wt. %, or about 0.5 wt. % to about 5 wt. % of the composition. In alternative embodiments the weight percent of surfactant in the composition, based on the total weight of the composition may be within any range having start and end points selected from the following: 0.1, 0.5, 1, 5, 10 and 15.

In some embodiments the compositions of this invention will be free of, or substantially free of, any or all surfactants and/or any of the above-listed types of surfactants in any combination (for examples zwitterionic and/or anionic surfactants) and/or any of the above-listed individual surfactants in any combination. For examples of the latter, the composition of the invention may be free of or substantially free of CTAB, and/or Surfynol® 485, and/or SAS10.

The etching compositions disclosed herein may also include one or more of the following additives: chelating agents, chemical modifiers, dyes, biocides, and other additives. The additive(s) may be added to the extent that they do not adversely affect the performance of the composition. The chelating agents include, for example, ethylenediaminetetraacetic acid (EDTA), butylenediaminetetraacetic acid, (1,2-cyclohexylenediamine)tetraacetic acid (CyDTA), diethylenetriaminepentaacetic acid (DETPA), ethylenediaminetetrapropionic acid, (hydroxyethyl)ethylenediaminetriacetic acid (HEDTA), N,N,N′,N′-ethylenediaminetetra(methylenephosphonic) acid (EDTMP), triethylenetetraminehexaacetic acid (TTHA), 1,3-diamino-2-hydroxypropane-N,N,N′,N′-tetraacetic acid (DHPTA), methyliminodiacetic acid, propylenediaminetetraacetic acid, nitrotriacetic acid (NTA), citric acid, tartaric acid, gluconic acid, saccharic acid, glyceric acid, oxalic acid, phthalic acid, maleic acid, mandelic acid, malonic acid, lactic acid, salicylic acid, propyl gallate, pyrogallol and cysteine. Preferred chelating agents are aminocarboxylic acids such as EDTA, CyDTA and aminophosphonic acids such as EDTMP.

In some embodiments the compositions of this invention will be free of or substantially free of any or all of the above-listed chelating agents in any combination. For example, the compositions may be free of aminocarboxylic acids and/or aminophosphonic acids and/or oxalic acid and/or cysteine and/or EDTA.

Other commonly known components such as dyes, biocides etc. can be included in the etching composition in conventional amounts, for example, amounts up to a total of about 5 weight % of the composition.

Alternatively, the compositions of this invention may be substantially free of, or free of, dyes and/or biocides and/or additives. Further, in some embodiments, the compositions of this invention may be substantially free of or free of one or more of the following in any combination: hydroxylamine or hydroxylamine derivatives, abrasives, inorganic acids, inorganic bases, oxidizers other than benzoquinones or derivatives of benzoquinones, peroxides, persulfates, nitrogen-containing heteroaromatic cyclic compounds excluding quinolines, fluoride-containing compounds, chloride-containing compounds, phosphorous-containing compounds, metal-containing compounds, ammonium hydroxide, amino acids, alkylamines, aniline or aniline derivatives, triazoles, 1,2,4 triazole, benzotriazole, and metal salts. In some embodiments, for an example, the compositions of the invention are free or substantially free of hydroxylamine and glycol ethers.

The etching solution compositions disclosed herein are typically prepared by mixing the components together in a vessel at room temperature until all solids have dissolved in the aqueous-based medium.

In another aspect there is provided a method for selectively enhancing the etch rate of polysilicon relative to p-doped silicon (or for selectively enhancing the etch rate of polysilicon relative to silicon-germanium) in a composite semiconductor device comprising silicon and p-doped silicon and/or silicon and SiGe by etching the composite semiconductor device in a composition comprising, consisting essentially of, or consisting of water; at least one of NH₄OH or a quaternary ammonium hydroxide; at least one compound selected from benzoquinone or a derivative of benzoquinone; quinoline or a derivative of quinoline; an unsubstituted or substituted C₆₋₂₀ aliphatic acid; a C₄₋₁₂ alkylamine and a polyalkylenimine, and mixtures thereof; optionally at least one water-miscible organic solvent; and optionally, at least one compound selected from the group consisting of an alkanolamine and a polyamine, and mixtures thereof; and optionally a fluoride ion source. In another there is provided a method for selectively enhancing the etch rate of polysilicon relative to p-doped silicon (or for selectively enhancing the etch rate of silicon relative to silicon-germanium) in a composite semiconductor device comprising silicon and p-doped silicon (or comprising silicon and SiGe), by etching the composite semiconductor device in a composition comprising, consisting essentially of and consisting of water; at least one water-miscible organic solvent; at least one of NH₄OH or a quaternary ammonium hydroxide; at least one compound selected from the group consisting of an alkanolamine and a polyamine; optionally, at least one compound selected from the group consisting of a C₄₋₁₂ alkylamine, a polyalkylenimine, and a mercapto carboxylic acid (or C₆₋₂₀ aliphatic acid compounds); optionally, at least one fluoride ion source; at least one benzoquinone or derivatives of benzoquinone; optionally, a quinoline or derivative of quinoline; and optionally, a surfactant. The method of selectively enhancing the etch rate of silicon relative to p-doped silicon (or selectively enhancing the etch rate of silicon relative to SiGe) on a composite semiconductor device comprising silicon and p-doped silicon (or silicon and SiGe), the method comprising the steps of: contacting the composite semiconductor device comprising silicon and p-doped silicon (or silicon and SiGe) with an aqueous composition comprising, consisting essentially of, or consisting of water; at least one of NH₄OH or a quaternary ammonium hydroxide; at least one compound selected from benzoquinone or a derivative of benzoquinone; quinoline or a derivative of quinoline; an unsubstituted or substituted C₆₋₂₀ aliphatic acid; a C₄₋₁₂ alkylamine and a polyalkylenimine, and mixtures thereof; optionally at least one water-miscible organic solvent; and optionally, at least one compound selected from the group consisting of an alkanolamine and a polyamine, and mixtures thereof; and optionally a fluoride ion source. In another embodiment, the method comprises the steps of selectively enhancing the etch rate of silicon relative to p-doped silicon (or silicon relative to SiGe) on a composite semiconductor device comprising silicon and p-doped silicon (and/or silicon and SiGe), the method comprising the steps of: contacting the composite semiconductor device comprising silicon and p-doped silicon and/or silicon and SiGe with an aqueous composition comprising, consisting essentially of, or consisting of water; at least one water-miscible organic solvent; at least one of NH₄OH or a quaternary ammonium hydroxide; at least one compound selected from the group consisting of an alkanolamine and a polyamine; optionally, at least one compound selected from the group consisting of a C₄₋₁₂ alkylamine, a polyalkylenimine, and a mercapto carboxylic acid (or C₆₋₂₀ aliphatic acid compound); optionally, at least one fluoride ion source; at least one benzoquinone or derivatives of benzoquinone; optionally, a quinoline or derivative of quinoline; and optionally, a surfactant; and rinsing the composite semiconductor device after the silicon is at least partially removed. The selectivity of the etch for silicon over p-doped silicon provided by the compositions and methods of this invention is greater than 10, or greater than 20, or greater than 50 or greater than 100. And the selectivity of the etch for silicon over silicon-germanium provided by the compositions and method of this invention are greater than 10, or greater than 15, or greater than 20. An additional drying step may also be included in the method. “At least partially removed” means removal of at least 50% of the material, preferably at least 70% removal. Most preferably, at least 80% removal using the compositions of the present development.

The contacting step can be carried out by any suitable means such as, for example, immersion, spray, or via a single wafer process. The temperature of the composition during the contacting step is preferably from about 25 to 100° C. and more preferably from about 40 to 75° C.

Etching compositions disclosed herein surprisingly exhibit excellent etch selectivity for silicon over p-doped silicon and/or silicon over SiGe when used on substrates that include silicon and p-doped silicon and/or silicon and SiGe, such as, for example, during the manufacture of a stacked gate all around device. The term “selectivity” is typically used to refer to a ratio of etch rates of two materials. Compositions according to the present invention preferably exhibit a wet etch selectivity for silicon over p-doped silicon of greater than or equal to 20, or greater than or equal to 40, or greater than 60, or greater than 100, or between from about 20 to about 500, or between from about 40 to about 500, or between from about 100 to about 500. In other embodiments, the etch selectivity for silicon over p-doped silicon observed with the composition of the present invention is between about 100 and about 300. And the selectivity of silicon over silicon-germanium is greater than 10, or greater than 15, or greater than 20, or between from about 10 to about 200.

After the contacting step is an optional rinsing step. The rinsing step may be carried out by any suitable means, for example, rinsing the substrate with de-ionized water by immersion or spray techniques. In preferred embodiments, the rinsing step may be carried out employing a mixture of de-ionized water and an organic solvent such as, for example, isopropyl alcohol.

After the contacting step and the optional rinsing step is an optional drying step that is carried out by any suitable means, for example, isopropyl alcohol (IPA) vapor drying, heat, or by centripetal force.

The features and advantages are more fully shown by the illustrative examples discussed below.

### EXAMPLES

General Procedure for Preparing the Etching Compositions

All compositions which are the subject of the present Examples were prepared by mixing the components in a 250 mL beaker with a 1″ Teflon-coated stir bar. Typically, the first material added to the beaker was deionized (DI) water followed by the other components in no particular order.

Processing Conditions

Etching tests were run using 100 g of the etching compositions in a 250 ml beaker with a ½″ round Teflon stir bar set at 400 rpm. The etching compositions were heated to a temperature of about 50 to 60° C. on a hot plate. The test coupons were immersed in the compositions for about 10 minutes while stirring.

The segments were then rinsed for 3 minutes in a DI water bath or spray and subsequently dried using filtered nitrogen. The polysilicon and p-doped silicon etch rates and the polysilicon and silicon-germanium etch rates were estimated from changes in the thickness before and after etching and was measured by spectroscopic ellipsometry (SCI FilmTek SE2000). Typical starting layer thicknesses were from 200-1000 Å for each of the Si, p-doped silicon and SiGe films on blank wafers.

The temperature of the polysilicon etching solution disclosed herein, i.e., the temperature used upon etching the dummy gate, is typically from about 20 to about 80° C., preferably from about 20 to about 70° C. and more preferably from about 20 to about 60° C. The temperature of the etching solution upon use may be appropriately determined according to etching conditions or material of the substrate used.

The treating time upon the etching treatment with the silicon etching solutions disclosed herein, i.e., the time required for etching the dummy gate, is usually in the range of from about 0.1 to about 10 min, preferably from 0.2 to 8 min and more preferably from 0.3 to 5 min, and may be appropriately determined according to etching conditions or material of the substrate used. In other embodiments, the time required for etching the dummy gate, is usually in the range of from about 0.1 to about 30 min, preferably from 0.2 to 20 min and more preferably from 0.3 to 10 min.

The formulations evaluated below demonstrate that the oxide etch rate could be suppressed by adding the various components described above.

### Example 1

### Evaluation of Various Functional Groups

Molecules with different functional groups were evaluated for their protection of p-doped silicon as listed in Table 1. Where the results indicate SiP (p-doped silicon) etch rate >500 A, this means that the layer was completely removed after 30 seconds of immersion.

TABLE 1
SiP Etch Rate with Different Additives.

| | 2290 | 316A | 316B | 316C | 316D | 316E | 316F | 316G | 316H | 316I | 316J | 316K |
|---|---|---|---|---|---|---|---|---|---|---|---|---|
| ETMAH(20%) | 15 | 15 | 15 | 15 | 15 | 15 | 15 | 15 | 15 | 15 | 15 | 15 |
| DIW | 50 | 50 | 50 | 50 | 50 | 50 | 50 | 50 | 50 | 50 | 50 | 50 |
| Monoethanolamine | 35 | 35 | 35 | 35 | 35 | 35 | 35 | 35 | 35 | 35 | 35 | 35 |
| (MEA) | | | | | | | | | | | | |
| octylamine | | 0.2 | | | | | | | | | | |
| decanoic acid | | | 0.2 | | | | | | | | | |
| 11- | | | | 0.1 | | | | | | | | |
| mercaptoundecanoic | | | | | | | | | | | | |
| acid | | | | | | | | | | | | |
| lupasol 800 | | | | | 0.2 | | | | | | | |
| CTAB | | | | | | 0.2 | | | | | | |
| surfynol 485 | | | | | | | 0.2 | | | | | |
| SAS10 | | | | | | | | 0.2 | | | | |
| 8-hydroxyquinoline | | | | | | | | | 0.2 | | | |
| (8HQ) | | | | | | | | | | | | |
| 1,2,4 triazole | | | | | | | | | | 0.2 | | |
| Benzotriazole | | | | | | | | | | | 0.2 | |
| cysteine | | | | | | | | | | | | 0.2 |
| SiP etch rate @ 50 C. | >500 | 2.3 | >500 | 2.8 | 3.6 | >500 | >500 | >500 | >500 | >500 | >500 | >500 |
| Poly Si etch rate @ | 543 | 550 | 549 | 549 | 538 | 542 | 160 | 223 | 522 | 547 | 531 | 546 |
| 50 C. | | | | | | | | | | | | |

From Table 1, it can be seen that compounds with long chain alkylamine or thiol molecules can inhibit SiP etch rate in an alkaline formulation. The non-ionic and anionic surfactants did not protect the SiP but also reduced the etch rate of the poly Si. The control was formulation 2290.

### Example 2

### Evaluation of Oxidizers and Benzoquinones

The approach was to selectively oxidize the SiP with an oxidizer. The resulting thin oxide layer acts as a protective layer against attack of hydroxide ions. The compositions and results are listed in Table 2.

TABLE 2
Investigation of Oxidizing Agents and benzoquinones

| | 334A | 334B | 334C | 334D | 334E | 531F | 531G | 531H |
|---|---|---|---|---|---|---|---|---|
| ETMAH(20%) | 12.5 | 12.5 | 12.5 | 12.5 | 12.5 | 12.5 | 12.5 | 12.5 |
| DMSO | 10 | 10 | 10 | 10 | 10 | 10 | 10 | 10 |
| DIW | 18 | 18 | 18 | 18 | 18 | 18 | 18 | 18 |
| Diethylenetriamine(DETA) | 10 | 10 | 10 | 10 | 10 | 10 | 10 | 10 |
| Propylene Glycol (PG) | 49.5 | 39.5 | 48.5 | 46.5 | 49 | 49 | 49 | 49 |
| H2O2 (30%) | | 10 | 1 | | | | | |
| Ammonium persulfate (APS) | | | | 3 | | | | |
| p-Benzoquinone | | | | | 0.5 | | | |
| 2-Methyl-p-benzoquinone | | | | | | 0.5 | | |
| 2,5-Dihydroxy-1,4- | | | | | | | 0.5 | |
| benzoquinone | | | | | | | | |
| 2-tert-Butyl-1,4-benzoquinone | | | | | | | | 0.5 |
| SiP etch rate @ 60 C. | >500 | 1.7 | 1.2 | 1.5 | 1.3 | 1.5 | 1.2 | 1.4 |
| Poly Si etch rate @ 60 C. | 264 | 4.5 | 4.9 | 6.8 | 216 | 223 | 210 | 198 |

From Table 2, it can be seen that both poly Si and SiP films were oxidized by H₂O₂ or ammonium persulfate, resulting in a decrease of etch rate on the two films. Benzoquinone exhibited good selectivity toward SiP and poly Si compared to H₂O₂ and APS. Similar performance was observed on p-benzoquinone derivatives like 2-methyl-p-benzoquinone, 2,5-dihydroxyl-p-benzoquinone and 2-t-butyl-p benzoquinone.

### Example 3

### Evaluation of Auxiliary Corrosion Inhibitors

The compositions and results are listed in Table 3.

TABLE 3
Auxiliary SiP Corrosion Inhibitors

| | 534M | 534N | 534P | 534Q | 534R | 534S | 534T |
|---|---|---|---|---|---|---|---|
| p-benzoquinone | 0.5 | 0.5 | 0.5 | 0.5 | 0.5 | 0.5 | 0.5 |
| DIW | 15 | 20 | 25 | 30 | 25 | 25 | 25 |
| Propylene Glycol (PG) | 56.5 | 51.5 | 46.5 | 41.5 | 36.5 | 44.5 | 46 |
| ETMAH (20%) | 8 | 8 | 8 | 8 | 8 | 8 | 8 |
| Diethylenetriamine(DETA) | 20 | 20 | 20 | 20 | 20 | 20 | 20 |
| HF(5%) | | | | | 10 | | |
| NH4F(40%) | | | | | | 2 | |
| NH4HF2 | | | | | | | 0.5 |
| SiP etch rate @ 60 C. | 1.3 | 1.2 | >500 | >500 | 1.2 | 1.1 | 1.2 |
| Poly Si etch rate @ 60 C. | 194 | 225 | 314.3 | 392.7 | 286 | 275 | 249 |

From Table 3 it can be seen that as the DIW content increases, the poly Si etch rate trends up due to the generation of more hydroxide ions. This shows that for some embodiments the total water content should not exceed 70 wt. % and, preferably should be less than 70 wt. %. The fluoride ions were found to be a good auxiliary corrosion inhibitor.

### Example 4

### Auxiliary SiGe Corrosion Inhibition

SiGe has shown promise in its performance as a source/drain material in pMOS transistors. From our studies, quinolines, like 8-hydroxyquinoline or 2-methyl-8-hydroxyquinoline provides good SiGe protection as shown in Table 4.

TABLE 4

| | 327J | 327N | 327O | 327R | 327T |
|---|---|---|---|---|---|
| p-benzoquinone | 0.7 | 0.7 | 0.7 | 0.7 | 0.7 |
| ETMAH(20%) | 15 | 15 | 15 | 15 | 15 |
| DIW | 50 | 50 | 50 | 50 | 50 |
| Monoethanolamine (MEA) | 35 | 35 | 35 | 35 | 35 |
| 8-hydroxyquinoline (8HQ) | 0 | 0.9 | 0 | 0 | 0 |
| 2-methyl-8hydroxyquinoline | 0 | 0 | 0.9 | 0 | 0 |
| (2M8HQ) | | | | | |
| 11-mercaptoundecanoic acid | 0 | 0 | 0 | 0.9 | 0 |
| Decanoic acid | 0 | 0 | 0 | 0 | 0.9 |
| SiGe etch rate @ 60 C. | 12.7 | 4.1 | 3.6 | 3.8 | 4.2 |
| SiP etch rate @ 60 C. | 1.8 | 1.3 | 1.4 | 1.5 | 1.4 |
| Poly Si etch rate @ 60 C. | 249 | 234 | 228 | 221 | 225 |

Here, it can be seen that 8-hydroxyquinoline and 2-methyl-8-hydroxyquinoline improved the SiGe compatibility and maintained acceptable SiP and poly Si etch rates.

### Example 5

### Evaluation of Solvents

The poly Si etch rate is typically controllable with different methods such as adjusting DIW level, process temperature, pH, and quaternary amine (TMAH, TEAH, or TBAH) selection. Here, it was observed that water-miscible solvents also play a role in controlling poly Si etch rate, which has strong relationship with its dielectric constant. As shown in Table 5, the poly Si etch rate increased as the dielectric constant increased.

TABLE 5
Solvent Effects

| | 353C | 353D | 353E | 353F | 353G | 353H | 353I |
|---|---|---|---|---|---|---|---|
| p-benzoquinone | 0.5 | 0.5 | 0.5 | 0.5 | 0.5 | 0.5 | 0.5 |
| ETMAH(20%) | 15 | 15 | 15 | 15 | 15 | 15 | 15 |
| DIW | 39.5 | 39.5 | 39.5 | 39.5 | 39.5 | 39.5 | 39.5 |
| Monoethanolamine (MEA) | 25 | 25 | 25 | 25 | 25 | 25 | 25 |
| DMSO | 20 | | | | | | |
| Sulfolane | | 20 | | | | | |
| Propylene Glycol (PG) | | | 20 | | | | |
| Ethylene Glycol (EG) | | | | 20 | | | |
| Glycerol | | | | | 20 | | |
| Dipropylene glycol monomethyl | | | | | | 20 | |
| ether (DPM) | | | | | | | |
| DIW | | | | | | | 20 |
| Poly Si etch rate @ 55 C. | 145 | 133 | 123 | 139 | 150 | 91 | 220 |
| dielectric constant | 47.3 | 44.0 | 27.5 | 41.4 | 46.0 | 10.5 | 80.0 |

### Example 6

### Evaluation of Amines

Here, we evaluated the effects of amines, including alkanolamines (such as MEA, AEE, MIPA) and polyamines such as DETA. The SiP and SiGe etch rates didn't show significant differences with the different amines, but some changes on poly Si etch rate were observed. The compositions and results are listed in Table 6.

TABLE 6
Amine Effect with Benzoquinones

| | 356I | 356V | 356W | 356X |
|---|---|---|---|---|
| p-benzoquinone | 0.8 | 0.8 | 0.8 | 0.8 |
| DMSO | 5.00 | 5.00 | 5.00 | 5.00 |
| ETMAH(20%) | 25.00 | 25.00 | 25.00 | 25.00 |
| DIW | 41.80 | 41.80 | 41.80 | 41.80 |
| 8-hydroxyquinoline (8HQ) | 0.90 | 0.90 | 0.90 | 0.90 |
| l-Amino-2-propanol (MIPA) | 25.00 | | | |
| Monoethanolamine (MEA) | | 25.00 | | |
| 2-(2-Aminoethoxy)-ethanol (AEE) | | | 25.00 | |
| Diethylenetriamine(DETA) | | | | 25.00 |
| SiP etch rate @ 55 C. | 0.6 | 0.5 | 0.7 | 0.6 |
| Poly Si etch rate @ 55 C. | 132.3 | 82.0 | 92.0 | 223.0 |
| SiGe etch rate @ 55 C. | 3.2 | 3.0 | 2.3 | 2.0 |

### Example 7

### Evaluation of Quaternary Ammonium hydroxides

Quaternary ammonium hydroxide as a hydroxide source to etch polysilicon were evaluated. The compositions and results are listed in Table 7.

TABLE 7
Quaternary Amines

| | 542C | 542D | 542E | 542F |
|---|---|---|---|---|
| Methyl-p-benzoquinone | 0.5 | 0.5 | 0.5 | 0.5 |
| DIW | 15 | 15 | 15 | 15 |
| Propylene Glycol (PG) | 56.5 | 56.5 | 56.5 | 56.5 |
| Diethylenetriamine(DETA) | 20 | 20 | 20 | 20 |
| Ethy Itrimethylammonium hydroxide | 8 | | | |
| (ETMAH), 20% | | | | |
| tetramethylammonium hydroxide | | 6.5 | | |
| (TMAH), 25% | | | | |
| tetraethylammonium hydroxide | | | 5 | |
| (TEAH), 40% | | | | |
| Benzyl trimethylammonium hydroxide | | | | 8 |
| (TritonB), 20% | | | | |
| SiP etch rate @ 60 C. | 0.5 | 0.6 | 0.5 | 0.7 |
| Poly Si etch rate @ 60 C. | 213 | 181 | 174 | 201 |

In addition to tetramethylammonium hydroxide (TMAH), derivatives such as ethyl trimethylammonium hydroxide (ETMAH), tetraethylammonium hydroxide (TEAH) and benzyl trimethylammonium hydroxide (Triton B) also exhibit good selectivity toward polysilicon and SiP.

TABLE 8
Additional Examples of the Invention: polysilicon and SiP in different
quaternary ammonium hydroxide solutions with methyl-p-benzoquinone

| | 575R | 575S | 575G | 575L | 575H | 575M | 575N |
|---|---|---|---|---|---|---|---|
| Methyl-p-benzoquinone | 0.3 | 0.3 | 0.3 | 0.3 | 0.3 | 0.3 | 0.3 |
| Ammonium Hydroxide (30%) | 10 | 20 | 0 | 0 | 0 | 0 | 0 |
| ETMAH (20%) | 0 | 0 | 5 | 7.5 | 10 | 0 | 0 |
| TEAH (40%) | 0 | 0 | 0 | 0 | 0 | 2.5 | 3.75 |
| DIW | 89.7 | 79.7 | 94.7 | 92.2 | 89.7 | 97.2 | 95.95 |
| Total | 100 | 100 | 100 | 100 | 100 | 100 | 100 |
| poly Si e/r at 60 C. | 45 | 95 | 113.82 | 296.1 | 448.8 | 51 | 102 |
| SiP e/r at 60 C. | 2.2 | 2.9 | 3.8 | 4.5 | 5.6 | 2.4 | 2.9 |
| poly Si/SiP selectivity | 20.5 | 32.8 | 30.0 | 65.8 | 80.1 | 21.3 | 35.2 |

TABLE 9
Additional Examples of the Invention, measuring the SiGe
etch rate: different inhibitors for SiGe etch rates

| | 575C | 575G | 575P | 575S | 575U | 575V | 575W | 575X |
|---|---|---|---|---|---|---|---|---|
| ETMAH(20%) | 5 | 5 | 5 | 5 | 5 | 5 | 5 | 5 |
| DIW | 95 | 94.7 | 94.5 | 94.7 | 94.4 | 94 | 94 | 94 |
| Methyl-p-benzoquinone | 0 | 0.3 | 0 | 0 | 0 | 0 | 0 | 0 |
| Decanoic acid | 0 | 0 | 0.5 | 0 | 0 | 0 | 0 | 0 |
| 11-mercaptoundecanoic | 0 | 0 | 0 | 0.3 | 0 | 0 | 0 | 0 |
| acid | | | | | | | | |
| 8-Hydroxyquinoline | 0 | 0 | 0 | 0 | 0.6 | 0 | 0 | 0 |
| 1,2,4 triazole | 0 | 0 | 0 | 0 | 0 | 1 | 0 | 0 |
| Benzotriazole | 0 | 0 | 0 | 0 | 0 | 0 | 1 | 0 |
| cysteine | 0 | 0 | 0 | 0 | 0 | 0 | 0 | 1 |
| Total | 100 | 100 | 100 | 100 | 100 | 100 | 100 | 100 |
| SiGe etch rate @ 60 C. | 38.8 | 10.9 | 19.2 | 9.8 | 12.3 | 39.2 | 37.6 | 33.4 |
| Poly Si etch rate @ 60 C. | 514.0 | 113.8 | 265.5 | 241.4 | 216.6 | 521.4 | 516.3 | 522.8 |

TABLE 10
Comparative Examples:

| | 575A | 575B | 575C |
|---|---|---|---|
| Ammonium Hydroxide (30%) | 5 | 0 | 0 |
| TEAH (40%) | 0 | 2.5 | 0 |
| ETMAH (20%) | 0 | 0 | 5 |
| DIW | 95 | 97.5 | 95 |
| Total | 100 | 100 | 100 |
| poly Si e/r at 60 C. | 248 | 361 | 514 |
| SiP e/r at 60 C. | >1000 | >1000 | >1000 |
| poly Si/SiP selectivity | 0.2 | 0.4 | 0.5 |

The foregoing description is intended primarily for purposes of illustration. Although the invention has been shown and described with respect to an exemplary embodiment thereof, it should be understood by those skilled in the art that the foregoing and various other changes, omissions, and additions in the form and detail thereof may be made therein without departing from the spirit and scope of the invention.

1. An etching solution suitable for the selective removal of polysilicon over p-doped silicon and/or polysilicon over silicon germanium alloy from a microelectronic device, comprising:
water;
at least one of NH₄OH or a quaternary ammonium hydroxide (neat), and mixtures thereof;
at least one compound selected from benzoquinone or a derivative of benzoquinone; quinoline or a derivative of quinoline; an unsubstituted or substituted C₆₋₂₀ aliphatic acid; a C₄₋₁₂ alkylamine; and a polyalkylenimine; and mixtures thereof;
optionally at least one water-miscible organic solvent; and
optionally, at least one compound selected from an alkanolamine and a polyamine, and mixtures thereof.

2. The etching solution of claim 1 comprising:
from about 0.05 to about 15 wt % of said at least one of NH₄OH (neat) or a quaternary ammonium hydroxide (neat);
from about 0.01 to about 8 wt % of said at least one compound selected from a benzoquinone or a derivative of benzoquinone; quinoline or a derivative of quinoline; an unsubstituted or substituted C₆₋₂₀ aliphatic acid; a C₄₋₁₂ alkylamine and a polyalkylenimine, and mixtures thereof.

3. The etching solution of claim 1, wherein the etching solution comprises said at least one compound selected from benzoquinone or a derivative of benzoquinone.

4. The etching solution of claim 1, wherein the etching solution comprises said at least one unsubstituted or substituted C₆₋₂₀ aliphatic acid.

5. The etching solution of claim 1, wherein the etching solution further comprises said at least one water-miscible organic solvent.

6. The etching solution of claim 1, wherein the etching solution further comprises at least one polyamine.

7. The etching solution of claim 1, wherein the etching solution further comprises at least one alkanolamine.

8. The etching solution of claim 1, wherein the etching solution comprises said at least one compound selected from a quinoline or a derivative of quinoline.

9. The etching solution of claim 1, wherein the etching solution comprises said at least one polyalkylenimine.

10. The etching solution of claim 1, wherein the etching solution comprises said at least one C₄₋₁₂ alkylamine.

11. The etching solution of claim 1, comprising:
water;
at least one water-miscible organic solvent;
at least one of NH₄OH or a quaternary ammonium hydroxide;
at least one compound selected from the group consisting of an alkanolamine and a polyamine or mixtures thereof;
at least one benzoquinone or a derivative of benzoquinone;
optionally, at least one compound selected from the group consisting of a C₄₋₁₂ alkylamine, a polyalkylenimine, and an unsubstituted or substituted C₆₋₂₀ aliphatic acid;
optionally, at least one fluoride ion source;
optionally, a quinoline or derivatives of quinoline; and
optionally, a surfactant.

12. The etching solution of claim 1, wherein the etching solution comprises from about 70 to about 99.9 wt % of said water.

13. The etching solution of claim 1, wherein the etching solution comprises from about 30 to about 70 wt % water.

14. The etching solution of claim 1, wherein the water-miscible organic solvent is selected from the group consisting of sulfolane, DMSO, ethylene glycol, glycerol, dipropylene glycol monomethyl ether, and propylene glycol.

15. The etching solution of claim 1, wherein the water-miscible organic solvent is dipropylene glycol monomethyl ether.

16. The etching solution of claim 1, wherein the quaternary ammonium hydroxide compound is selected from tetramethylammonium hydroxide, tetraethylammonium hydroxide, tetrapropylammonium hydroxide, tetrabutylammonium hydroxide, benzyltrimethyl ammonium hydroxide, ethyltrimethyl ammonium hydroxide (ETMAH), 2-hydroxyethyltrimethyl ammonium hydroxide, benzyltriethyl ammonium hydroxide, hexadecyltrimethyl ammonium hydroxide, and mixtures thereof.

17. The etching solution of claim 1, wherein the alkanolamine compound is selected from N-methylethanolamine (NMEA), monoethanolamine (MEA), diethanolamine, triethanolamine, mono-isopropanolamine, triisopropanolamine, 2-(2-aminoethylamino)ethanol, 2-(2-aminoethoxy)ethanol (AEE), triethanolamine, N-ethyl ethanolamine, N,N-dimethylethanolamine, N,N-diethyl ethanolamine, N-methyl diethanolamine, N-ethyl diethanolamine, cyclohexylaminediethanol, diisopropanolamine, cyclohexylaminediethanol, and mixtures thereof.

18. The etching solution of claim 1, wherein the polyalkylenimine is polyethylenimine.

19. The etching solution of claim 1, wherein the substituted or unsubstituted C₆₋₂₀ aliphatic acid is selected from hexanoic acid, heptanoic acid, octanoic acid, nonanoic acid, decanoic acid, undecanoic acid, dedecanoic acid, 6-mercaptohexanoic acid, 7-mercaptoheptanoic acid, 8-mercaptooctanoic acid, 9-mercaptononanoic acid, 10-mercaptodecanoic acid, 11-mercaptoundecanoic acid, 12-mercaptododecanoic acid and 16-mercaptohexadecanoic acid.

20. The etching solution of claim 1, wherein the unsubstituted or substituted C₆₋₂₀ aliphatic acid is a mercapto carboxylic acid.

21. The etching solution of claim 1, wherein the benzoquinone or a derivative of benzoquinone is selected from 1,4-benzoquinone, o-benzoquinone, 2-methyl-1,4-benzoquinone, 2,5-dihydroxyl-p-benzoquinone, and 2-tert-butyl-1,4-benzoquinone, 2-phenyl-1,4-benzoquinone, 2-methoxy-1,4-benzoquinone; 2,6-dimethyl-1,4-benzoquinone; 2,3-dimethyl-1,4-benzoquinone; trimethyl-1,4-benzoquinone; 2,6-dimethoxy-1,4-benzoquinone; tetramethyl-1,4-benzoquinone; tetrafluoro-1,4-benzoquinone; 2,5-dichloro-1,4-benzoquinone; tetrachloro-1,4-benzoquinone; 2-chloro-1,4-benzoquinone; 1,4-naphthoquinone; 9,10-anthraquinone; 1,8-dichloro-9,10-anthraquinone; 2,3-dichloro-1,4-naphthoquinone; 3,5-di-tert-butyl-1,2-benzoquinone; 4-tert-butyl-1,2-benzoquinone; phenanthrenequinone; 1,2-naphthoquinone; 1,10-phenanthroline-5,6-dione; and
tetrachloro-1,2-benzoquinone.

22. The etching solution of claim 1, wherein the benzoquinone or a derivative of benzoquinone is present in the solution and is selected from p-benzoquinone, o-benzoquinone, 2-methyl-p-benzoquinone, 2,5-dihydroxyl-p-benzoquinone, and 2-t-butyl-p benzoquinone.

23. The etching solution of claim 1, wherein the polyamine is selected from pentamethyldiethylenetriamine (PMDETA), triethylenediamine (TEDA), triethylenetetramine (TETA), tetramethylethylenediamine (TMEDA), and diethylenetriamine (DETA).

24. The etching solution of claim 1, wherein the quinoline or a derivative of quinoline is selected from quinoline, 8-hydroxy quinoline, 2-methyl-8-hydroxyquinoline and aminoquinoline.

25. The etching solution of claim 1, wherein the C₄₋₁₂ alkylamine is selected from hexylamine, surfactant salts of hexylamine, octylamine, surfactant salts of octylamine, decylamine, surfactant salts of decylamine, and dodecylamine, and surfactant salts of dodecylamine.

26. The etching solution of claim 11 comprising water;
methyl-p-benzoquinone;
propylene glycol;
diethylenetriamine; and
at least one quaternary ammonium hydroxide selected from the group consisting of ethyltrimethylammonium hydroxide, tetramethylammonium hydroxide, tetraethylammonium hydroxide, and benzyl trimethylammonium hydroxide.

27. The etching solution of claim 26 further comprising C₆₋₂₀ aliphatic acid.

28. A method for selectively enhancing the etch rate of polysilicon relative to p-doped silicon and/or polysilicon relative silicon germanium alloy in a composite semiconductor device comprising polysilicon and p-doped silicon and/or comprising polysilicon and germanium alloy, the method comprising the steps of:
contacting the composite semiconductor device comprising polysilicon and p-doped silicon and/or polysilicon and a silicon-germanium alloy with the aqueous composition of claim 1 and
rinsing the composite semiconductor device after the polysilicon is at least partially removed.

29. The method of claim 28, wherein the selectivity of polysilicon relative to p-doped silicon is greater than 10.

30. (canceled)

31. (canceled)

32. The method of claim 28, wherein the selectivity of the etch for polysilicon over silicon-germanium alloy is greater than about 10.

33. (canceled)

34. (canceled)
